(19) United States
(12) Patent Application Publication
(10) Pub. No.: US 2014/0131707 A1
(43) Pub. Date: May 15, 2014

(54) METHOD AND DEVICE FOR DETECTING TERMINATION OF ETCHING

(71) Applicant: Fuji Electric Co., Ltd., Kanagawa (JP)

(72) Inventors: Hiroshi Tomizawa, Fukushima (JP); Takuya Furuichi, Saitama (JP)

(73) Assignee: Fuji Electric Co., Ltd., Kanagawa (JP)

(21) Appl. No.: 14/110,128

(22) PCT Filed: Nov. 12, 2012
(86) PCT No.: PCT/JP2012/007255

§ 371 Date: Dec. 9, 2013

(30) Foreign Application Priority Data
Nov. 14, 2011 (JP) 2011-248861

(51) Int. Cl. H01L 21/66

(52) U.S. Cl. CPC H01L 22/14; H01L 22/30
USPC 257/48; 438/18

(57) ABSTRACT

Provide is an etching completion detection method that accurately detects an etching completion position in an SOI substrate, regardless of the width of an opening. This etching completion detection method is a method for detecting etching completion when a silicon layer is being etched to form an opening that reaches an insulating layer in an SOI substrate in which the silicon layer is disposed on the insulating layer, the method including: forming a first electrode layer on a surface of an islet region that is surrounded by a loop-shaped opening to be formed by the etching, and a second electrode layer in a region outside the stripe region; measuring an electrical resistance between the first electrode layer and the second electrode layer; and determining that the loop-shaped opening has reached an etching completion position when the electrical resistance exceeds a preset threshold.

### TECHNICAL FIELD

The present invention relates to a method and device for detecting etching completion in an SOI substrate in which a silicon layer is disposed on an insulating layer, when the silicon layer is being etched to form a loop-shaped opening that reaches the insulating layer.

### BACKGROUND ART

In a capacitive acceleration sensor that has a movable electrode and a fixed electrode for detecting an acceleration based on a change in capacitance, the movable electrode and the fixed electrode are formed on an SOI substrate.

In order to manufacture the capacitive acceleration sensor, a plurality of grooves are patterned on a surface of the SOI substrate into shapes corresponding to the movable electrode and the fixed electrode by using, for example, a resist, and thereafter a silicon layer of the SOI substrate is subjected to dry etching. In an etching processing method used in this case, a processing time until an insulating layer below the silicon layer is exposed is calculated beforehand, and the depth of the grooves are measured by using a laser microscope or the like to monitor whether the silicon layer is etched down to the insulating layer. There is another method in which a unique plasma emission spectrum that is generated by a product of reaction between etching gas and silicon is monitored, and when the intensity of the plasma emission spectrum falls to a predetermined value or less as a result of completely etching off the silicon layer, it is determined that the etching is ended.

However, when the structure of the section to be processed is miniaturized, it is difficult to measure the depth of the grooves using a laser microscope or the like, and the light intensity of the unique wavelength generated by the plasma is lowered, making it difficult to accurately detect whether the etching is ended or not.

In the prior art, there is proposed an etching completion detection method, in which a layer to be etched is etched via a mask under the condition same as or equivalent to that of the etching on a section to be processed; a portion of the layer to be etched corresponding to an opening part is removed down to an etching stopping material; side etching occurs along the etching stopping material; a portion of the layer to be etched corresponding to a portion for detection is detached from the etching stopping material; and etching completion is detected by the detachment (see Patent Document 1, for example).

There is also disclosed a method of manufacturing a semiconductor device, in which an impurity layer in the same depth as a desired groove depth is formed under the surface of a semiconductor substrate made of silicon, a mask is formed on this semiconductor substrate, a groove is formed by ion plasma etching, then electrical resistance between both sides across the groove in the semiconductor substrate is measured using a measuring probe, and the etching is stopped as soon as the resistance rises rapidly (see Patent Document 2, for example).

There is also proposed an etching end-point control pattern in which, when a semiconductor thin film composed of low-resistance n⁺ amorphous silicon is formed on a high-resistance semiconductor layer (made of polysilicon, for example) on a surface of an insulating layer, and when a conductive resist pattern is formed on this semiconductor thin film to etch only the low-resistance thin film, thereby leaving a pattern in the shape of an islet, an inspection region is formed in the vicinity of a desired pattern by forming two islet patterns facing each other, in such a manner that a residue of a low-resistance region can be detected by measuring an electrical resistance (see Patent Document 3, for example).

### RELATED ART DOCUMENTS

### Patent Documents

Patent Document 1: Japanese Patent Application Publication No. 2006-150563

Patent Document 2: Japanese Patent Application Publication No. S60-167332

Patent Document 3: Japanese Patent Application Publication No. S62-256438

### SUMMARY OF THE INVENTION

### Problems to be Solved by the Invention

According to the conventional example described in Patent Document 1, when the SOI substrate is etched, completion of the etching can physically be detected when the etching progresses to reach the insulating layer after the silicon layer. In other words, detachment of the portion of the layer to be etched, which corresponds to the portion for detection, from the etching stopping material, is detected, the detachment being caused by the side etching occurring along the etching stopping material after the etching on the silicon layer is completed. However, the problem of the conventional example described in Patent Document 1 is that the timing for detecting the completion of the etching is delayed, because the detachment of the portion of the layer to be etched for detection is detected using the side etching occurring along the etching stopping material after the etching progresses to reach the etching stopping material.

In each of the conventional examples described in Patent Documents 2 and 3, on the other hand, the completion of the etching on not the SOI substrate but the semiconductor substrate is detected based on the changes of the resistance. In the conventional example described in Patent Document 2, the measuring probes are applied, through the masks, to the impurity layers on both sides of the groove that is etched therein. Therefore, how the measuring probes are applied affects the measurement results. Moreover, due to the narrow range in which the electrical resistances is detected, it cannot be determined whether the etching is completed or not in a relatively long range.

The problem of Patent Document 3 is that it is necessary to form a low-resistance semiconductor thin film on a high-resistance semiconductor layer and to form a conductive mask on this semiconductor thin film, and in addition, it requires a step of removing the mask after completion of the etching. Therefore, this conventional example cannot be applied to a case in which an insulating mask is used as an etching mask as in an SOI substrate.

The present invention was contrived in view of these unsolved problems of the conventional examples, and an object of the present invention is to provide a method and apparatus for detecting etching completion, capable of accurately detecting the etching completion time at which a groove formed by etching of a silicon layer of an SOI substrate reaches an insulating layer.

### Means for Solving the Problems

In order to achieve this object, a first aspect of an etching completion detection method according to the present invention is a method for detecting etching completion when a conductive silicon layer is being etched to form a loop-shaped opening that reaches an insulating layer in an SOI substrate in which the conductive silicon layer is disposed on the insulating layer. The etching completion detection method includes: constructing an etching completion detector by disposing a first electrode portion on a surface of an islet region that is surrounded by the loop-shaped opening to be formed by the etching, and a second electrode portion in a region outside the islet region; measuring an electrical resistance between the first electrode portion and the second electrode portion; and determining that the loop-shaped opening has reached an etching completion position when the electrical resistance exceeds a preset threshold.

According to this first aspect, when forming a groove in the silicon layer of the SOI substrate down to the insulating layer by etching, the first electrode portion and the second electrode portion are disposed on the surface of the islet region and in the region outside the islet region, respectively, the islet region being surrounded by the loop-shaped opening to be formed by the etching. Then, the electrical resistance between the electrode portions is measured. At this stage, when the depth of the etched loop-shaped opening forming the islet region does not yet reach the insulating region, the islet region and the outer region that face each other with the loop-shaped opening therebetween remain connected by the silicon layer. Hence, the electrical resistance between the first and second electrode portions remains low. Thereafter, when the etching progresses to the point where the depth of the etched loop-shaped opening becomes as deep as the insulating layer, the first electrode portion and the second electrode portion are connected to each other by the insulating layer. Therefore, the electrical resistance between the first and second electrode portions exceeds the preset threshold, and becomes high. As a result, the fact that the loop-shaped opening has reached the etching completion position can be detected.

In a second aspect of the etching completion detection method according to the present invention, the etching for the loop-shaped opening is performed while measuring the electrical resistance between the first electrode portion and the second electrode portion; and the loop-shaped opening is determined to have reached the etching completion position when the electrical resistance exceeds the preset threshold.

According to the second aspect, because the etching for the loop-shaped opening is performed while measuring the electrical resistance, the etching can be ended when the loop-shaped opening has reached the etching completion position, whereby the loop-shaped opening that reaches the insulating layer can be formed accurately.

In a third aspect of the etching completion detection method according to the present invention, the loop-shaped opening is in the form of a circular or polygonal loop-shaped groove.

According to the third aspect, because the loop-shaped opening is in the form of a circular or polygonal loop-shaped groove, the islet region and the region outside the islet region are certainly insulated from each other by the loop-shaped groove without being electrically connected, when the loop-shaped groove has reached to the etching completion position. In this manner, the etching completion position can be detected accurately.

In a fourth aspect of the etching completion detection method according to the present invention, the etching completion detector is formed in a region different from a section to be processed which is etched simultaneously with the loop-shaped opening.

According to the fourth aspect, even when a non-loop-shaped opening is formed in the section to be processed, the etching completion detector can detect that the opening of the section to be processed has reached the etching completion position.

In a fifth aspect of the etching completion detection method according to the present invention, the etching completion detector is formed on an SOI substrate on which the section to be processed is formed.

According to the fifth aspect, because the etching completion detector is formed on the SOI substrate on which the section to be processed is formed, the etching completion detector can accurately detect that the opening of the section to be processed has reached the etching completion position.

In a sixth aspect of the etching completion position detection method according to the present invention, the etching completion detector is formed on an SOI substrate that is different from an SOI substrate on which the section to be processed is formed.

According to the sixth aspect, it is only necessary to form the etching completion detector on a single SOI substrate, when the etching completion detector cannot be formed on an SOI substrate on which a section to be processed is formed, or when a plurality of SOI substrates with sections to be processed need to be etched simultaneously. Thus, the cost of manufacturing SOI substrates can be reduced.

In a seventh aspect of the etching completion detection method according to the present invention, the loop-shaped opening is configured to have a width equal to a width of an opening of the section to be processed.

According to the seventh aspect, because the width of the loop-shaped opening of the etching completion detector is set to be equal to the width of the opening of the section to be processed, the time to end the etching for the loop-shaped opening can accurately be conformed to the time to end the etching for the opening of the section to be processed.

In an eighth aspect of the etching completion detection method according to the present invention, the etching completion detector is configured by a plurality of etching completion detectors respectively having different etching speeds.

According to the eighth aspect, the completion of the etching can be detected in stages by using the plurality of etching completion detectors. Thus, the completion of the etching can be detected more accurately.

A first aspect of an etching completion detection device according to the present invention is a device for detecting etching completion when a conductive silicon layer is being etched to form an opening that reaches an insulating layer in an SOI substrate in which the conductive silicon layer is disposed on the insulating layer. The etching completion detection device includes an etching completion detector that has an loop-shaped opening to be formed by the etching and reaching the insulating layer, an islet region surrounded by the loop-shaped opening, a first electrode portion disposed on a surface of the islet region, and a second electrode portion disposed in a region outside the islet region. The etching completion detection device further includes an etching completion determination unit that measures an electrical resistance between the first electrode portion and the second electrode portion by using a resistance measuring device, and determines that the loop-shaped opening has reached an etching completion position when the electrical resistance exceeds a preset threshold.

### Effects of the Invention

According to the present invention, the first electrode portion is disposed in the islet region that is surrounded by the loop-shaped opening to be etched down to the insulating layer, and the second electrode portion is disposed in the region outside the islet region. The electrical resistance between the electrode portions is measured. When the etching progresses to the point where the depth of the etched loop-shaped opening becomes as deep as the insulating layer, the electrical resistance exceeds the preset threshold, whereby the completion of the etching can be detected accurately.

### BRIEF DESCRIPTION OF THE DRAWINGS

FIG. 1 is a plan view showing an SOI substrate applicable to an etching completion detection method according to the present invention.

FIG. 2 shows an etching completion detector of FIG. 1. FIG. 2(a) is a plan view and FIG. 2(b) a cross-sectional diagram taken along line A-A of FIG. 2(a).

FIG. 3 is an explanatory diagram showing a method of forming electrodes in the etching completion detector.

FIG. 4 is an explanatory diagram showing the etching completion detection method.

FIG. 5 is a diagram showing changes in resistance occurring during etching.

FIG. 6 is an explanatory diagram showing another example of the etching completion detection method.

FIG. 7 is an explanatory diagram showing another example of the etching completion detector.

FIG. 8 is an explanatory diagram showing yet another example of the etching completion detector.

### BEST MODE FOR CARRYING OUT THE INVENTION

An embodiment of the present invention is described hereinafter with reference to the drawings.

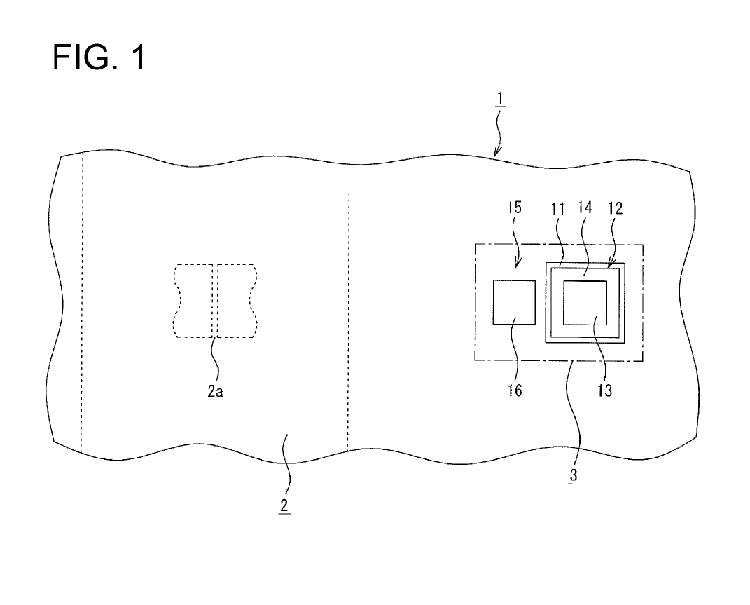

FIG. 1 is a plan view showing an SOI (Silicon-On-Insulator) substrate applicable to an etching method according to the present invention.

In the diagram, reference numeral 1 represents an SOI substrate. In this SOI substrate 1, there are formed a section to be processed 2 for forming various MEMS (Micro Electro Mechanical Systems) sensors, such as a pressure sensor, an acceleration sensor, an angular velocity sensor, and an attitude sensor, and an etching completion detector 3 formed away from the section to be processed 2.

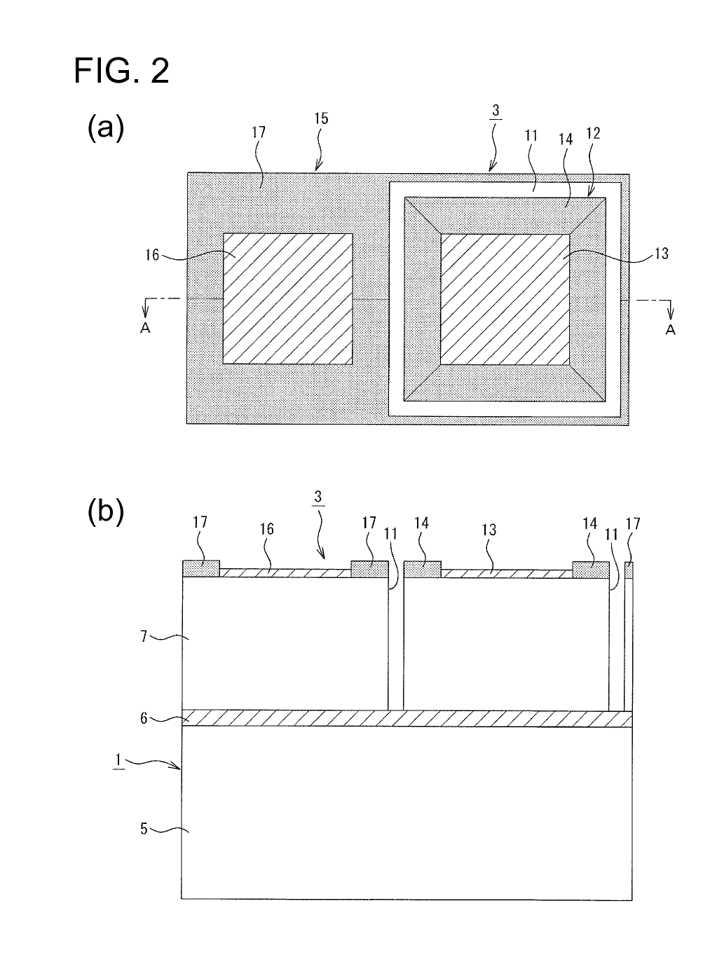

As shown in FIG. 2(b), the SOI substrate 1 is configured by forming an etching stop layer 6, composed of an insulating layer, on a base 5 and forming a layer to be etched 7 on the etching stop layer 6. The base 5 and the layer to be etched 7 are made primarily of silicon exhibiting low-resistance characteristics as represented by a specific resistance ranging from 0.01 to 0.04 Ω·cm. The etching stop layer 6 is normally an insulating film composed of an oxide film and has high-resistance characteristics.

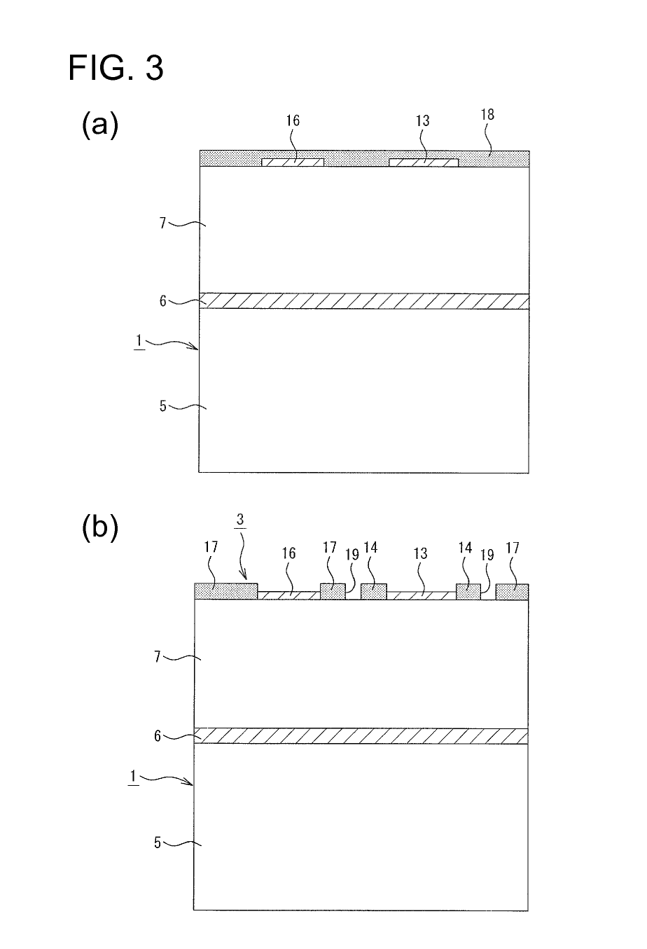

In the section to be processed 2, an opening 2a is formed, by dry etching, into the shape of a groove or space to reach at least the etching stop layer 6 shown in FIG. 3. For the dry-etching, RIE (Reactive Ion Etching) using a CCP (Capacitively Coupled Plasma), ICP (Inductive Coupled Plasma), ECR (Electron Cyclotron Resonance) plasma and the like can be employed.

As shown by the enlarged view in FIG. 2, the etching completion detector 3 has an islet region 12 that is surrounded by a loop-shaped opening 11 that is to be formed by dry etching to reach the etching stop layer 6. The loop-shaped opening 11 forms a loop-shaped groove in the shape of a square frame in a plan view. It is preferable that the width of the loop-shaped opening 11 be equal to the width of the opening 2a of the section to be processed. The islet region 12 has, at the center of its surface, a first electrode portion 13 that is formed into, for example, a shape similar to the square shape of the loop-shaped opening 11. Aluminum or aluminum alloy, for example, which is not etched by the dry etching, is preferably employed as the first electrode portion 13. An insulating mask 14 used in etching the loop-shaped opening 11 is formed around the first electrode portion 13.

Furthermore, a second electrode portion 16 having the same shape as the first electrode portion 13 is formed on a surface of an outer region 15 outside the islet region 12 across the loop-shaped opening 11. As with the first electrode portion, aluminum or aluminum alloy, for example, which is not etched by the dry etching, is preferably employed as the second electrode portion 16. A mask 17 used in etching the loop-shaped opening 11 is formed around the second electrode portion 16 outside the loop-shaped opening 11.

In forming the etching completion detector 3, first, the first electrode portion 13 and the second electrode portion 16 of aluminum or aluminum alloy are vapor-deposited or sputtered on an upper surface of the layer to be etched 7, and then a mask layer 18 that becomes an insulating layer is formed thereon in such a manner as to cover the first electrode portion 13 and the second electrode portion 16, as shown in FIG. 3(a). Subsequently, as shown in FIG. 3(b), the mask layer 18 is etched to expose the first electrode portion 13 and the second electrode portion 16 and to form a loop-shaped opening 19 at a portion that will face the loop-shaped opening 11, thereby forming the masks 14 and 17.

As in the etching completion detector 3, the mask 17 also has an opening at a portion that will face the opening 2a of the section to be processed 2.

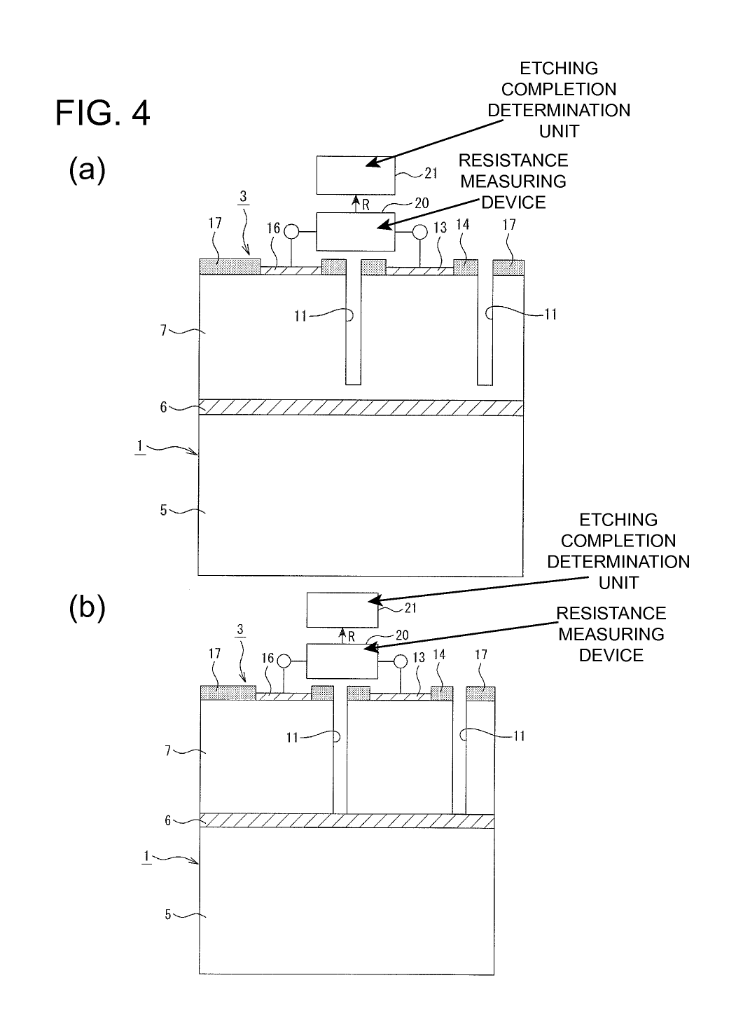

When dry-etching the SOI substrate 1 configured as described above, first, as shown in FIG. 4(a), a resistance measuring device 20 such as a multitester is connected between the first electrode portion 13 and the second electrode portion 16, and an etching completion determination unit 21 is connected to a resistance measurement value output side of the resistance measuring device 20.

Subsequently, only the SOI substrate 1 is installed in a dry etching apparatus. At this stage, in a case where dry etching is not yet started, an electrical resistance R to be measured by the resistance measuring device 20 is less than 1 kΩ (R<1 kΩ) when the specific resistance ρ of the layer to be etched 7 is 0.01 to 0.04 Ω·cm.

When dry etching is started in such a state, etching progresses in the loop-shaped opening 11 between the masks 14 and 17, as well as on the opening 2a of the section to be processed 2.

Even when the etching depth becomes close to the etching stop layer 6 as shown in FIG. 4(a), the electrical resistance R measured by the resistance measuring device 20 remains less than 1 kΩ, due to the presence of the relatively thick layer to be etched 7 between the loop-shaped opening 11 and the etching stop layer 6.

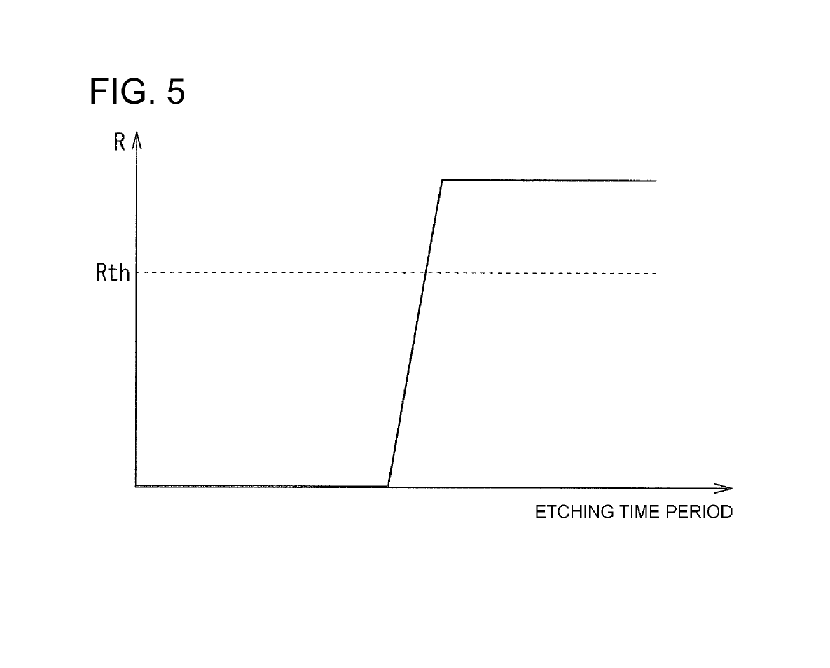

However, when the loop-shaped opening 11 reaches the etching stop layer 6 as shown in FIG. 4(b), the electrical resistance R measured by the resistance measuring device 20 rises rapidly, as shown in FIG. 5. Consequently, when the specific resistance ρ of the layer to be etched 7 is 0.01 to 0.04 Ω·cm as described above, the electrical resistance R to be measured rises rapidly to exceed 1 GΩ (R>1 GΩ), due to the high resistance value of the etching stop layer 6.

At this moment—i.e., when the measured electrical resistance R exceeds a preset threshold Rth, the etching completion determination unit 21 determines that the depth of the etched loop-shaped opening 11 has reached the etching stop layer 6, which is an etching completion position, and then causes the dry etching performed by the dry etching apparatus to end.

In this case, in order to ensure that the loop-shaped opening 11 reaches the etching stop layer 6, the etching is ended with a delay of a relatively short, predetermined delay time after the measured electrical resistance R exceeds the threshold Rth. In this manner, the etching can be ended when the loop-shaped opening 11 certainly reaches the etching stop layer 6.

By matching the width of the loop-shaped opening 11 of the etching completion detector 3 and the width of the opening 2a of the section to be processed 2 to be actually etched, the depth of the etched opening 2a of the section to be processed 2 becomes as deep as the etching stop layer 6 as soon as the etching completion detector 3 detects the completion of the etching. Therefore, the completion of the etching can accurately be managed.

According to the present embodiment, when the electrical resistance R between the first electrode portion 13 and the second electrode portion 16 that is measured by the resistance measuring device 20 reaches the threshold Rth after dry etching is started, the dry etching is stopped. Thus, the fact that the loop-shaped opening 11 has reached the etching stop layer 6 can accurately be detected.

Because the first electrode portion 13 and the second electrode portion 16 with the loop-shaped opening 11 therebetween are formed into squares, the electrical resistance R rapidly rises when the substantially entire loop-shaped opening 11 facing the electrode portions 13 and 16 reaches the etching stop layer 6. Because it is determined that the etching is ended when the loop-shaped opening 11 facing the first electrode portion 13 and the second electrode portion 16 reaches the etching stop layer 6 over substantially the entire length of the loop-shaped opening 11, the completion of the etching can accurately be detected even when the speed of etching in a circumferential direction of the loop-shaped opening 11 varies.

The etching completion detector 3 is independent of the section to be processed 2, and the first electrode portion 13 and the second electrode portion 16 are formed especially for the etching completion detector 3. Therefore, it is not necessary to remove the first electrode portion 13 and the second electrode portion 16 after completion of the etching, thus eliminating an electrode removal step.

In the embodiments described above, the moment when the electrical resistance R measured by the resistance measuring device 20 exceeds the threshold Rth is detected as the etching completion time at which the loop-shaped opening 11 has reached the etching stop layer 6. However, the present invention is not limited to this. When the loop-shaped opening 11 completely reached the etching stop layer 6, the electrical resistance R reaches saturation as shown in FIG. 5, and this saturation may be detected to end the etching.

Moreover, the etching may be ended when etching is executed for an etching time period that is measured in advance, instead of executing dry etching while measuring the electrical resistance R between the first electrode portion 13 and the second electrode portion 16 by using the resistance measuring device 20 as described above. In this case, it is preferable that the time for this dry etching be set based on a time period between the etching start time and the etching completion time, which was measured when dry etching is executed while measuring the electrical resistance R in a manner described above.

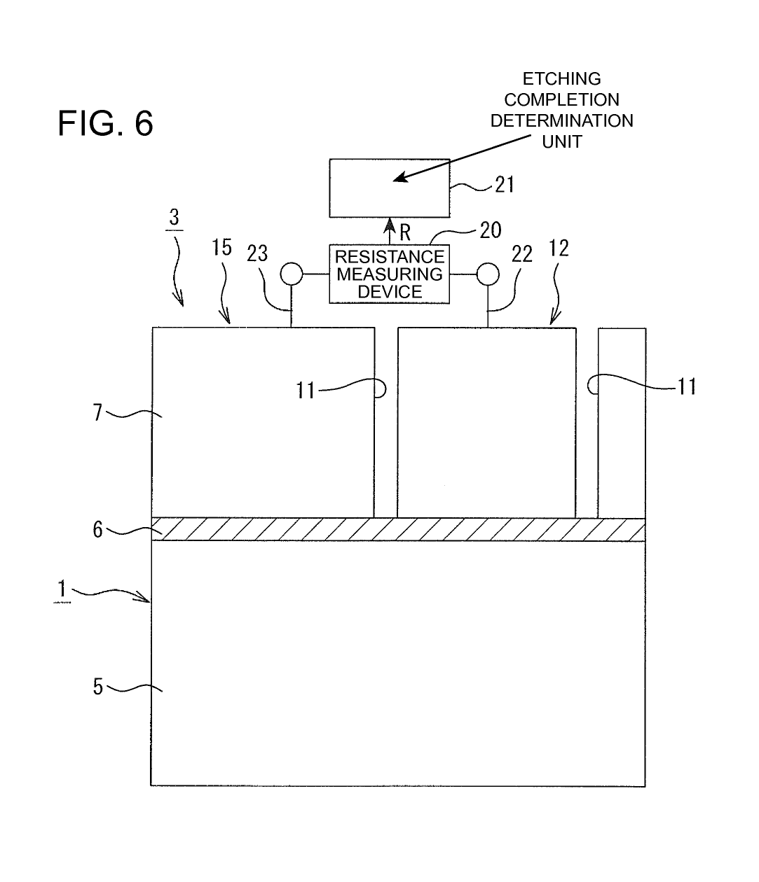

In this case, it is not necessary to measure the electrical resistance R while performing the dry etching. Thus, the first electrode portion 13 does not need to be formed in the islet region 12, nor does the second electrode portion 16 need to be in the region 15 that faces the islet region 12 with the loop-shaped opening 11 therebetween, as shown in FIG. 6. Therefore, the entire surface can be covered by the masks.

Then, whether the loop-shaped opening 11 of the SOI substrate 1 that is etched for the set etching time period has reached the etching stop layer 6 or not is confirmed by measuring the electrical resistance R between the islet region 12 and the outer region 15 by using the resistance measuring device 20.

In other words, in a state shown in FIG. 6 in which the masks are removed to expose the surfaces of the islet region 12 and the outer region 15, the electrical resistance R is measured using the resistance measuring device 20 by bringing probes 22 and 23 into contact with, respectively, the surfaces of the islet region 12 and the outer region 15 adjacent thereto across the loop-shaped opening 11 in respective potions where the electrodes would have been formed, each of the probes 22 and 23 being composed of a measuring pointer or an electrode piece wider than a measuring pointer. In so doing, when the measured electrical resistance R is equal to or greater than the threshold Rth or preferably reaches a saturation resistance value, it can be determined that the loop-shaped opening 11 and the opening 2a of the section to be processed 2 have certainly reached the etching stop layer 6, which is the etching completion position.

In the embodiments described above, the loop-shaped opening 11 of the etching completion detector 3 is in the shape of a square frame in a plan view; however, the present invention is not limited thereto. The loop-shaped opening 11 can be shaped into a triangle, a polygon of five or more sides, or a circle.

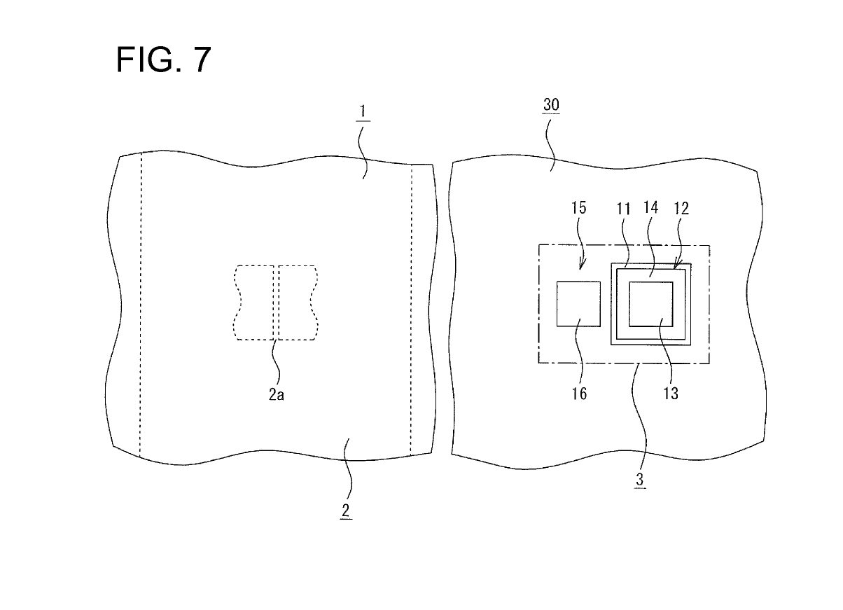

In the embodiments described above, the etching completion detector 3 is formed on the SOI substrate 1 having the section to be processed 2 formed thereon; however, the present invention is not limited thereto. As shown in FIG. 7, the etching completion detector 3 can be formed on an SOI substrate 30, which is different from the SOI substrate 1 having the section to be processed 2 formed thereon.

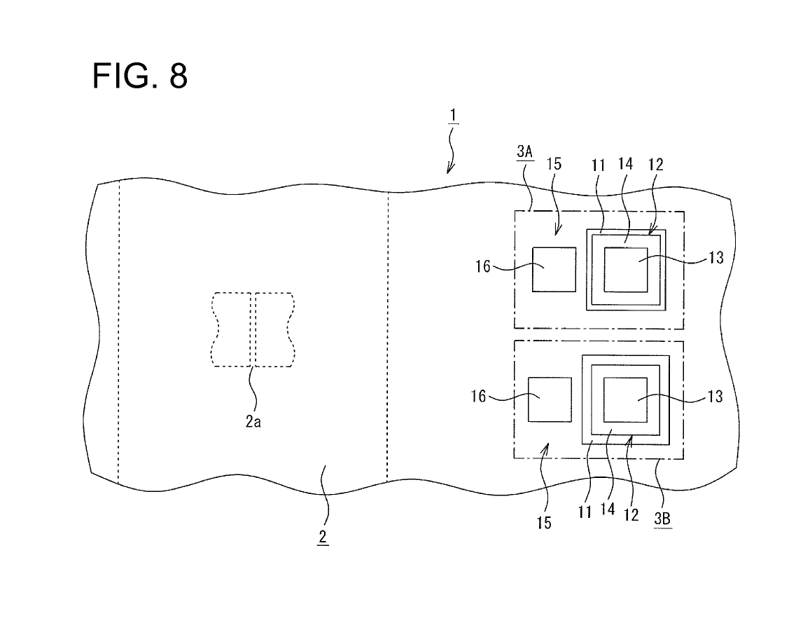

In the embodiments described above, a single etching completion detector 3 is formed. However, the present invention is not limited to the configuration described in the embodiments. As shown in FIG. 8, a plurality of, for example two, etching completion detectors 3A, 3B having the loop-shaped openings 11 of different widths are prepared. Then, the time to end the etching may be detected in stages by measuring the electrical resistance R between the first electrode portion 13 and the second electrode portion 16 of the respective etching completion detectors 3. In this case, the time to end the etching can be detected in stages because the etching speed drops as the width of the loop-shaped opening 11 narrows from the etching completion detector 3 having the wide loop-shaped opening 11.

### INDUSTRIAL APPLICABILITY

The present invention can provide a method and apparatus for detecting etching completion, capable of accurately detecting the etching completion time at which a groove formed by etching of a silicon layer of an SOI substrate reaches an insulating layer.

### EXPLANATION OF REFERENCE NUMERALS

1 . . . SOI substrate, 2 . . . Section to be processed, 3 . . . Etching completion detector, 5 . . . Base, 6 . . . Etching stop layer, 7 . . . Layer to be etched, 11 . . . Loop-shaped opening, 12 . . . Islet region, 13 . . . First electrode portion, 14 . . . Mask, 15 . . . Outer region, 16 . . . Second electrode portion, 20 . . . Resistance measuring device, 21 . . . Etching completion determination unit, 30 . . . SOI substrate

1. A method for determining etching time for etching a conductive silicon layer on an insulating layer to form a designed opening reaching the insulating layer in an SOI substrate, the method comprising:
constructing, on an SOI substrate having a conductive silicon layer and an insulating layer that are respectively identical to or equivalent to said conductive silicon layer and said insulating layer, an etching completion detector by disposing a first electrode portion on a surface of an islet region that is surrounded and defined by a loop-shaped opening that is formed in the conductive silicon layer when subject to the etching, and by disposing a second electrode portion in a region outside the islet region;
subjecting the SOI substrate having the etching completion detector formed thereon to said etching;
measuring an electrical resistance between the first electrode portion and the second electrode portion during said etching; and
determining that the loop-shaped opening has reached the insulating layer underneath when the electrical resistance exceeds a preset threshold, thereby determining the etching time for etching the conductive silicon layer to form the designed opening reaching the insulating layer.

2. The method according to claim 1, further comprising:
forming the designed opening at the same time as subjecting the SOI substrate having the etching completion detector formed thereon to said etching during which the electrical resistance between the first electrode portion and the second electrode portion is measured; and
determining that the designed opening has reached said insulating layer when the measured electrical resistance exceeds the preset threshold.

3. The method according to claim 1, wherein the loop-shaped opening is in the form of a circular or polygonal loop-shaped groove.

4. The method according to claim 1, wherein the etching completion detector is formed on the same SOI substrate as the SOI substrate in which the designed opening of the conductive silicon layer is to be formed, and the etching completion detector is formed in a region that is different from a region in which the designed opening of the conductive silicon layer is to be formed, which is etched simultaneously with the loop-shaped opening.

5. (canceled)

6. The method according to claim 1, wherein the etching completion detector is formed on an SOI substrate that is different from the SOI substrate on which the designed opening of the conductive layer is to be formed.

7. The method according to claim 1, wherein the loop-shaped opening has a width equal to a width of the designed opening of the conductive silicon layer to be formed.

8. The method according to claim 1, wherein there are provided said etching completion detectors respectively having different etching speeds.

9. A device for detecting etching completion when etching a conductive silicon layer on an insulating layer to form an opening that reaches the insulating layer in an SOI substrate, the device comprising:
an etching completion detector on the SOI substrate that will have a loop-shaped opening in the conductive silicon layer reaching the insulating layer when subject to the etching, the etching completion detector having an islet region surrounded and defined by the loop-shaped opening when subject to the etching, the etching completion detector further having a first electrode portion disposed on a surface of the islet region and a second electrode portion disposed in a region outside the islet region; and
an etching completion determination unit that measures an electrical resistance between the first electrode portion and the second electrode portion by a resistance measuring device, the etching completion determination unit determining that the loop-shaped opening has reached the insulating layer underneath when the electrical resistance exceeds a preset threshold.

10. The method according to claim 2, wherein the loop-shaped opening is in the form of a circular or polygonal loop-shaped groove.

11. The method according to claim 2, where in the etching completion detector is formed on the same SOI substrate as the SOI substrate on which the designed opening of the conductive silicon layer is to be formed, and the etching completion detector is formed in a region different from a region in which the designed opening of the conductive silicon layer is to be formed, which is etched simultaneously with the loop-shaped opening.

12. The method according to claim 2, wherein the loop-shaped opening has a width equal to a width of the designed opening of the conductive silicon layer to be formed.

13. The method according to claim 3, wherein the loop-shaped opening has a width equal to a width of the designed opening of the conductive silicon layer to be formed.

14. The method according to claim 4, wherein the loop-shaped opening has a width equal to a width of the designed opening of the conductive silicon layer to be formed.

15. The method according to claim 6, wherein the loop-shaped opening has a width equal to a width of the designed opening of the conductive silicon layer to be formed.

16. The method according to claim 2, wherein there are provided a plurality of said etching completion detectors respectively having different etching speeds.

17. The method according to claim 3, wherein there are provided a plurality of said etching completion detectors respectively having different etching speeds.

18. The method according to claim 4, wherein there are provided a plurality of said etching completion detectors respectively having different etching speeds.

19. The method according to claim 6, wherein there are provided a plurality of said etching completion detectors respectively having different etching speeds.
